(19) United States
(12) Patent Application Publication
(10) Pub. No.: US 2018/0010735 A1
(43) Pub. Date: Jan. 11, 2018

(54) Locking Articulating Mounting Systems and Methods

(71) Applicant: Roam Directories, Dallas, TX (US)

(72) Inventors: Dennis Smolek, Dallas, TX (US); James Tucker McCormack, Dallas, TX (US)

(21) Appl. No.: 15/643,708

(22) Filed: Jul. 7, 2017

Related U.S. Application Data
(60) Provisional application No. 62/359,981, filed on Jul. 8, 2016.

(51) Int. Cl. F16M 13/02; H05K 5/00; F16M 11/04

(52) U.S. Cl. CPC F16M 13/02; F16M 11/048; H05K 5/0017

(57) ABSTRACT

Systems and methods may provide a locking articulating mount. Small pieces of hardware, such as back pressure screws, may be used to lock a display in place. They can be adjusted to cause outward forces against the display away from the backing. A mount also may be adjustable for assembly, but when closed, may provide a significant reduction in play or movement. A latch may form part of the mount to hold the display against the inside edge that can only be released through a pull cable.

### CROSS REFERENCE TO RELATED APPLICATION

This application claims the benefit under 35 U.S.C. §119(e) of U.S. Provisional Patent Application Ser. No. 62/359,981 filed on Jul. 8, 2016, entitled “Locking Articulating Mounting Systems and Methods,” which is incorporated by reference in its entirety.

### FIELD OF THE DISCLOSURE

The present disclosure generally relates to mounting, and more particularly to mounting of a display that allows for locking as well as articulation.

### BACKGROUND

Mounting hardware presently on the market is designed to be easily adjustable and flexible. This results in tolerances, materials, as well as designs that do not take rigidity into account. When mounting touchscreens or other similar audio-visual equipment, this may result in a poor user experience, particularly lowering perception by users.

The industry standard for mounting touchscreens is set by the Video Electronics Standards Association (VESA), and this industry standard places mounting hardware in the direct center portion of touchscreen displays. As touchscreen displays have increased in size, this means that the distance between the direct center portion and an outer edge of the display can range from approximately 12 inches up to approximately 36 inches. Even using the best materials, flex and play can be serious issues for mounting of these types of displays.

There are generally two types of mounts that are available—fixed mounts and adjustable/articulating mounts. Fixed mounts are typically attached directly to a wall where the touchscreen display is to be mounted, and attachment hardware is affixed to the display. Once mated, the attachment hardware resides approximately 1 inch from the wall surface and relies on the weight of the display to “pull” against the attachment hardware. Adjustable or articulating mounts may allow the touchscreen display to be moved in different directions with minimal effort. While there are some locking mounts available, they are generally designed for use with recreational vehicles (RVs) so that a mounted television will not bang around inside the RV when it is in motion; however, these locking mounts generally still allow for a ¼″ in movement and they are thick in nature (i.e., the television is not very flush with a wall on which it is mounted). Other locking mounts have been provided for video walls where a display forming part of the wall can be pulled out for service, but these types of locking mounts are unsuitable for touchscreen displays.

### SUMMARY

Embodiments of the present disclosure may provide locking articulating mount systems and methods. In an embodiment of the present disclosure, small pieces of hardware, such as back pressure screws, may be used to lock a display in place. They can be adjusted to cause outward forces against the display away from the backing. A mount also may be adjustable for assembly in an embodiment of the present disclosure, but when closed, may provide a significant reduction in play or movement. A latch may form part of the mount in an embodiment of the present disclosure; the latch may be present to hold the display against the inside edge that can only be released through a pull cable.

Embodiments of the present disclosure may provide a display mount assembly, the assembly comprising: one or more backpressure screws affixed behind a display, wherein the one or more backpressure screws may be adjustable to press outward and cause negative resistance against the display to lock the display in place. The one or more backpressure screws do not mark or damage the display. The one or more backpressure screws may be used in conjunction with a Video Electronics Standards Association (VESA) mounting mechanism. The one or more backpressure screws may cause outward forces against the display away from a backing of the display while the VESA-based mounting mechanism may apply forces toward the backing. The one or more backpressure screws may not be visible when affixed behind the display. The assembly also may include a latch that holds the display against an inside edge of the display. The latch may be released using a pull cable. The latch may be spring-loaded. The display may be selected from the group comprising: a touchscreen display, a flat panel display, a kiosk display to be mounted within a boxed structure, and an audio-visual display. When the one or more backpressure screws are closed, there may be a reduction in play or movement of the display.

Further embodiments of the present disclosure may provide a display mount assembly comprising an arm base affixed to at least two inner arms; and at least two outer arms affixed to the at least two inner arms, wherein the at least two outer arms and the at least two inner arms provide for articulation of the display mount assembly when the display mount assembly is attached to a display. The assembly also may include an arm spacer to separate the at least two outer arms from the at least two inner arms. The at least two inner arms may further comprise a bolt, a washer, and a thin locknut to affix the at least two inner arms to the arm spacer. The assembly also may include a latch that holds the display against an inside edge of the display. The latch may be released using a pull cable. The latch may be spring-loaded. The display may be selected from the group comprising: a touchscreen display, a flat panel display, a kiosk display to be mounted within a boxed structure, and an audio-visual display. The assembly also may include a Video Electronics Standards Association (VESA) plate assembly.

Additional embodiments of the present disclosure may provide a display mount assembly, the assembly comprising: one or more backpressure screws affixed behind a display, wherein the one or more backpressure screws are adjustable to press outward and cause negative resistance against the display to lock the display in place; and a latch that may hold the display against an inside edge of the display, wherein play or movement of the display may be reduced when the latch is locked in place. The one or more backpressure screws may be used in conjunction with a Video Electronics Standards Association (VESA) mounting mechanism, and wherein the one or more backpressure screws may cause outward forces against the display away from a backing of the display while the VESA-based mounting mechanism may apply forces toward the backing.

### BRIEF DESCRIPTION OF THE DRAWINGS

For a more complete understanding of this disclosure, reference is now made to the following description, taken in conjunction with the accompanying drawings, in which:

FIG. 1 depicts a mount rotary assembly according to an embodiment of the present disclosure;

FIG. 2 depicts several views of a display mount assembly according to an embodiment of the present disclosure;

FIG. 3 depicts an exploded view of a backpressure screw according to an embodiment of the present disclosure as well as a view of the back pressure screw when put together; and

FIG. 4 depicts mounting according to an embodiment of the present disclosure including back pressure screws as well as a VESA-based mounting mechanism.

### DETAILED DESCRIPTION

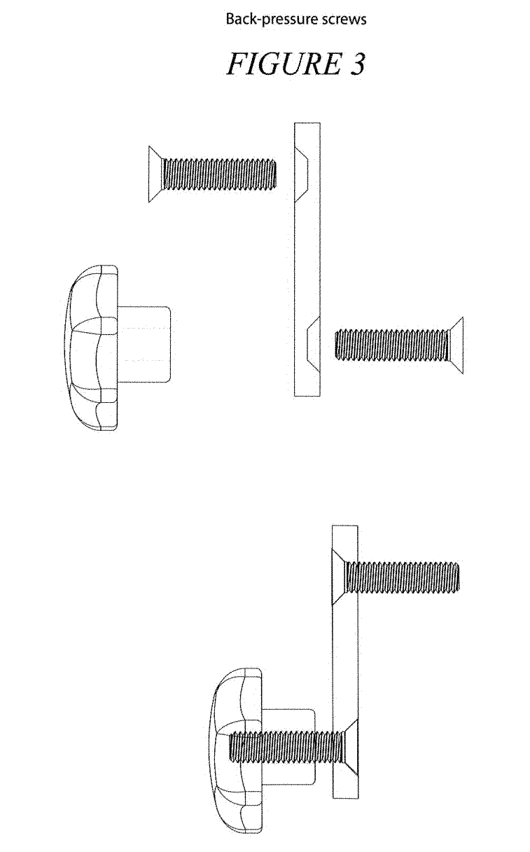

Using a fixed mount or a mount that locks the center of a display into place, small pieces of hardware, such as backpressure screws, may be affixed behind a touchscreen display that can be adjusted to press outward and cause negative resistance against the display. When fully adjusted outward, this fixed mounting method may remove any play in the mount itself. A small piece of hardware, such as one or more back pressure screws, may be attached to a rear wall surface and then adjusted to press against the back of a touchscreen display without marking or damaging the display. FIG. 3 depicts an exploded view of a backpressure screw according to an embodiment of the present disclosure as well as a view of the backpressure screw when put together.

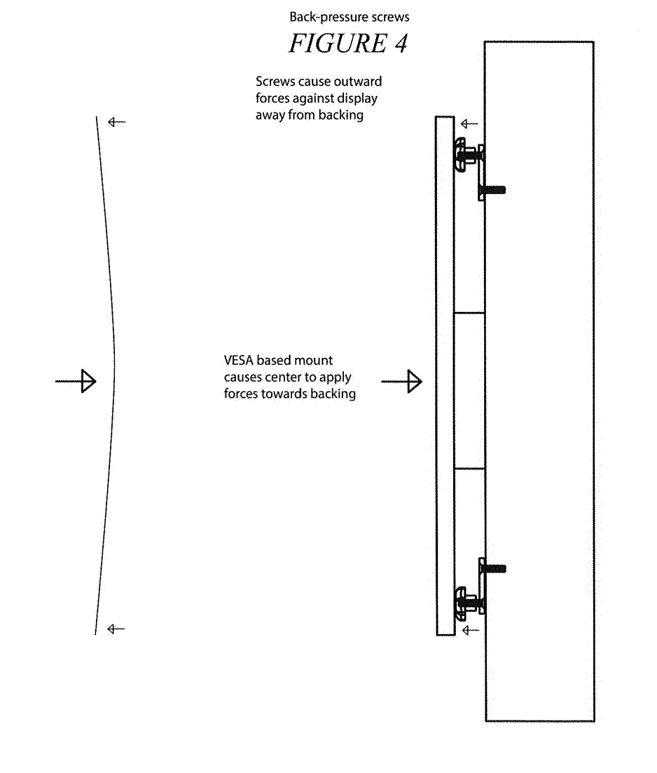

As depicted in FIG. 4, one or more back pressure screws according to embodiments of the present disclosure may cause outward forces against the display away from the backing, while the VESA-based mounting mechanism may cause the center to apply forces toward the backing. The backpressure screws may be loosened and push on the back of a display but then lock closed. When the display is locked in place, the screws may be not be visible when one looks at the edges of the display. Accordingly, use of these backpressure screws according to an embodiment of the present disclosure may also be aesthetically pleasing from a visual standpoint. Further, in some embodiments of the present disclosure, mounting plates may be provided with screws on the side so as to mount a display.

A mount according to embodiments of the present disclosure may have adjustability for installation; however, when closed, the mount may provide a significant reduction in play or movement of the touchscreen display. As described in more detail below, latch may hold the display against the inside edge that can only be released by a pull cable. Once released, the touchscreen display may be easily pulled out for service.

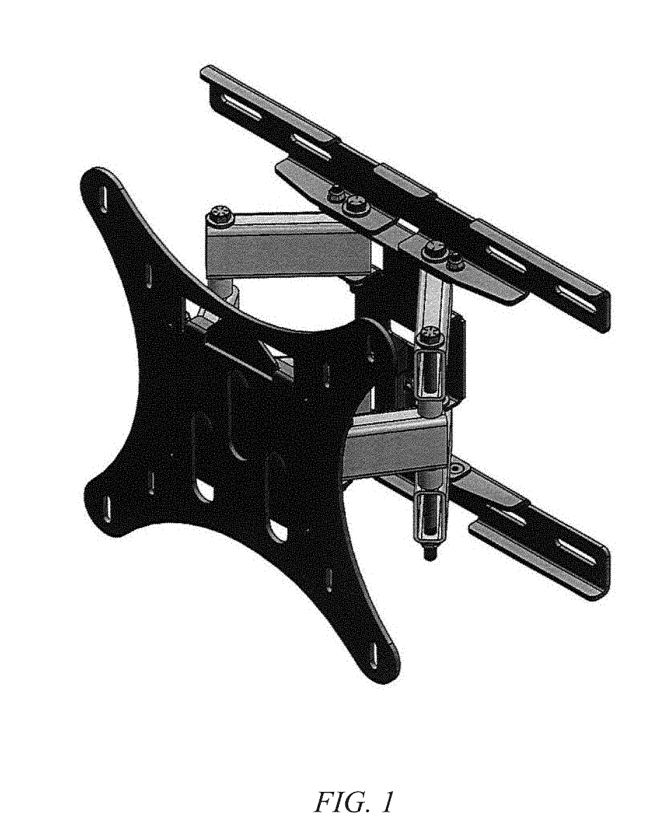

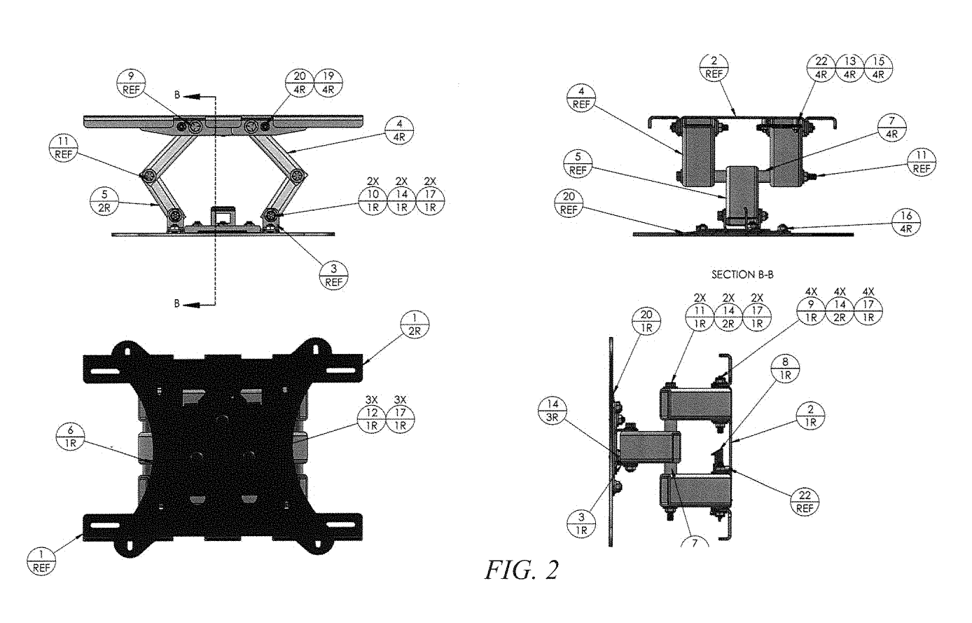

FIG. 1 depicts a display mount rotating assembly according to an embodiment of the present disclosure, and FIG. 2 depicts several views of a display mount assembly according to an embodiment of the present disclosure. As depicted in FIGS. 1 and 2, two wall brackets 1 may be provided to attach the mount assembly to the wall.

The assembly may include inner and outer arms that provide for articulation of the mount assembly. Inner arms 4 may be affixed to arm base 2, and socket cap 13, lock nut 15 and spacer 22 may be used for this attachment in an embodiment of the present disclosure. However, it should be appreciated that other affixing mechanisms may be used to affix inner arms 4 to arm base 2 without departing from the present disclosure. Also, bolt 11, washer 14 and thin locknut 17 may be used to affix inner arms 4 to arm spacer 7. Inner arms 4 also may include bolt 9, washer 14 and thin locknut 17 as another affixing mechanism in embodiments of the present disclosure. While mechanisms for affixing the arms to a base have been described, it should be appreciated that more, fewer or different components may be used for affixing without departing from the present disclosure.

As depicted in FIG. 2, the assembly may include latch 8 that may hold a display against the inside edge in an embodiment of the present disclosure. This latch 8 may allow the mount assembly to have adjustability during installation, but when locked in place, there may be a significant reduction in play or movement of the display. Latch 8 may be released using a pull cable or other similar mechanism, and once released, the display may be easily pulled out for service or to take other actions related to the display. It should be appreciated that latch 8 may be similar to a cabinet latch in an embodiment of the present disclosure. In some embodiments of the present disclosure, the latch may be spring-loaded; however, there may be other embodiments of the present disclosure where the latch may incorporate a pull cable. The pull cable may then be released in order to order unlock the display, such as for maintenance.

Bolts 11 may affix inner arms 4 to outer arms 5. Again, it should be appreciated that other affixing mechanisms may be used to attach inner arms 4 to outer arms 5 without departing from the present disclosure. Arm spacer 7 may be provided to separate inner arms 4 and outer arms 5 in some embodiments of the present disclosure. Again, while mechanisms for affixing the arms to each other have been described, it should be appreciated that more, fewer or different components may be used for affixing without departing from the present disclosure.

Outer arm base rotary 3 may be provided and may be affixed to outer arms 5 through flanged cap screw 10, washer 14 and flanged lock nut 17 in an embodiment of the present disclosure. However, as previously discussed, other affixing mechanisms may be utilized to attach outer arm base rotary 3 to outer arms 5 without departing from the present disclosure. Outer arm base rotary 3 may be affixed to intermediate rotation adapter 20 through socket cap 14 in an embodiment of the present disclosure, but other affixing mechanisms may be used without departing from the present disclosure. Intermediate rotation adapter 20 also may include lock nuts 16 or another similar affixing mechanism in embodiments of the present disclosure.

VESA plate assembly 6 may be included as part of the assembly depicted in FIGS. 1 and 2 to meet industry standards.

There may be some references herein to touchscreen displays; however, it should be appreciated that systems and methods according to embodiments of the present disclosure may be utilized for wall mounting other types of displays, such as flat panel displays, and other audio-visual equipment. It also should be appreciated that there may be other embodiments wherein the systems and methods may be used in a kiosk-like environment where a display be mounted inside of a boxed structure.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A display mount assembly, the assembly comprising:
one or more backpressure screws affixed behind a display, wherein the one or more backpressure screws are adjustable to press outward and cause negative resistance against the display to lock the display in place.

2. The assembly of claim 1, wherein the one or more backpressure screws do not mark or damage the display.

3. The assembly of claim 1, wherein the one or more backpressure screws are used in conjunction with a Video Electronics Standards Association (VESA) mounting mechanism.

4. The assembly of claim 3, wherein the one or more backpressure screws cause outward forces against the display away from a backing of the display while the VESA-based mounting mechanism applies forces toward the backing.

5. The assembly of claim 1, wherein the one or more backpressure screws are not visible when affixed behind the display.

6. The assembly of claim 1 further comprising:
a latch that holds the display against an inside edge of the display.

7. The assembly of claim 6, wherein the latch is released using a pull cable.

8. The assembly of claim 6, wherein the latch is spring-loaded.

9. The assembly of claim 1, wherein the display is selected from the group comprising:
a touchscreen display, a flat panel display, a kiosk display to be mounted within a boxed structure, and an audio-visual display.

10. The assembly of claim 1, wherein when the one or more backpressure screws are closed, there is a reduction in play or movement of the display.

11. A display mount assembly, the assembly comprising:
an arm base affixed to at least two inner arms; and
at least two outer arms affixed to the at least two inner arms, wherein the at least two outer arms and the at least two inner arms provide for articulation of the display mount assembly when the display mount assembly is attached to a display.

12. The assembly of claim 11 further comprising:
an arm spacer to separate the at least two outer arms from the at least two inner arms.

13. The assembly of claim 12, wherein the at least two inner arms further comprise a bolt, a washer, and a thin locknut to affix the at least two inner arms to the arm spacer.

14. The assembly of claim 11 further comprising:
a latch that holds the display against an inside edge of the display.

15. The assembly of claim 14, wherein the latch is released using a pull cable.

16. The assembly of claim 14, wherein the latch is spring-loaded.

17. The assembly of claim 11, wherein the display is selected from the group comprising:
a touchscreen display, a flat panel display, a kiosk display to be mounted within a boxed structure, and an audio-visual display.

18. The assembly of claim 11 further comprising:
a Video Electronics Standards Association (VESA) plate assembly.

19. A display mount assembly, the assembly comprising:
one or more backpressure screws affixed behind a display, wherein the one or more backpressure screws are adjustable to press outward and cause negative resistance against the display to lock the display in place; and
a latch that holds the display against an inside edge of the display, wherein play or movement of the display is reduced when the latch is locked in place.

20. The assembly of claim 19, wherein the one or more backpressure screws are used in conjunction with a Video Electronics Standards Association (VESA) mounting mechanism, and wherein the one or more backpressure screws cause outward forces against the display away from a backing of the display while the VESA-based mounting mechanism applies forces toward the backing.
